(19) United States
(12) Patent Application Publication
(10) Pub. No.: US 2022/0368288 A1
(43) Pub. Date: Nov. 17, 2022

(54) Amplifying Circuit and Voltage Generating Circuit

(71) Applicant: ROHM CO., LTD., Kyoto (JP)

(72) Inventors: Hiroyuki Aminaga, KYOTO (JP); Koji Saito, KYOTO (JP)

(21) Appl. No.: 17/742,645

(22) Filed: May 12, 2022

(30) Foreign Application Priority Data
May 17, 2021 (JP) 2021082956

(51) Int. Cl. H03F 1/30; G05F 1/575; G05F 1/567; G05F 1/46

(52) U.S. Cl. CPC H03F 1/303; G05F 1/575; G05F 1/567; G05F 1/468

(57) ABSTRACT

The present disclosure relates to an amplifying circuit and a voltage generating circuit. The amplifying circuit includes: an operational amplifier, including a first input terminal, a second input terminal and an output terminal, and configured to be capable of outputting an output voltage corresponding to an input voltage from the output terminal to the first input terminal; a voltage dividing circuit, including a series circuit of a plurality of voltage dividing resistors disposed between the output terminal and a predetermined potential terminal, wherein the series circuit includes a feedback node connected to the second input terminal and a correction node different from the feedback node; and a correction circuit, including a diode inserted between the correction node and the predetermined potential terminal.

### TECHNICAL FIELD

The present disclosure relates to an amplifying circuit and a voltage generating circuit.

### BACKGROUND

A voltage generated by a circuit varies according to the temperature. For example, a reference voltage source can generate a reference voltage having a predetermined direct-current (DC) voltage value. However, when the temperature of a circuit including the reference voltage source varies, the reference voltage also varies to a certain extent.

### PRIOR ART DOCUMENT

### Patent Publication

[Patent publication 1] Japan Patent Publication No. 2017-060383

### SUMMARY OF THE PRESENT DISCLOSURE

### Problems to be Solved by the Present Disclosure

In order to obtain a voltage having less temperature dependence, a structure, in which a voltage having temperature dependence is input to an amplifying circuit which then outputs a voltage having less temperature dependence, is discussed. However, it can be easily conceived that the input voltage input to the amplifying circuit has various temperature characteristics. For example, the input voltage does not change linearly in response to the temperature rise. It is desired to develop a structure that can respond to various temperature characteristics.

It is an object of the present disclosure to provide an amplifying circuit and a voltage generating circuit that help reduce temperature dependence.

### Technical Means for Solving the Problem

The amplifying circuit of the present disclosure includes: an operational amplifier, including a first input terminal, a second input terminal and an output terminal, and configured to be capable of outputting an output voltage corresponding to an input voltage from the output terminal to the first input terminal; a voltage dividing circuit, including a series circuit of a plurality of voltage dividing resistors disposed between the output terminal and a predetermined potential terminal, wherein the series circuit includes a feedback node connected to the second input terminal and a correction node different from the feedback node; and a correction circuit, including a diode inserted between the correction node and the predetermined potential terminal.

### Effects of the Present Disclosure

According to the present disclosure, an amplifying circuit and a voltage generating circuit that help reduce temperature dependence are provided.

### BRIEF DESCRIPTION OF THE DRAWINGS

FIG. 1 is a structural diagram of a voltage generating circuit according to an embodiment of the present disclosure.

FIG. 2 is a diagram of an example of an input voltage supply circuit according to an embodiment of the present disclosure.

FIG. 3 is a structural diagram of a voltage generating circuit according to a first embodiment of the embodiments of the present disclosure.

FIG. 4 is a diagram of temperature dependence of an input voltage according to the first embodiment of the embodiments of the present disclosure.

FIG. 5 is a structural diagram of a voltage generating circuit according to the first embodiment of the embodiments of the present disclosure.

FIG. 6 is a diagram of temperature dependence of an amplification factor according to the first embodiment of the embodiments of the present disclosure.

FIG. 7 is a diagram of temperature dependence of an output voltage according to the first embodiment of the embodiments of the present disclosure.

FIG. 8 is a diagram of temperature dependence of an input voltage according to a second embodiment of the embodiments of the present disclosure.

FIG. 9 is a structural diagram of a voltage generating circuit according to the second embodiment of the embodiments of the present disclosure.

FIG. 10 is a diagram of temperature dependence of an amplification factor according to the second embodiment of the embodiments of the present disclosure.

FIG. 11 is a diagram of temperature dependence of an output voltage according to the second embodiment of the embodiments of the present disclosure.

FIG. 12 is a diagram of adjusting temperature dependence of an amplification factor according to the second embodiment of the embodiments of the present disclosure.

FIG. 13 is a diagram of adjusting temperature dependence of an amplification factor according to the second embodiment of the embodiments of the present disclosure.

FIG. 14 is a diagram of a variation structure of a voltage generating circuit according to the second embodiment of the embodiments of the present disclosure.

FIG. 15 is a structural diagram of a voltage generating circuit according to a third embodiment of the embodiments of the present disclosure.

FIG. 16 is a diagram of temperature dependence of an amplification factor according to the third embodiment of the embodiments of the present disclosure.

### DETAILED DESCRIPTION OF THE EMBODIMENTS

Details of the embodiments of the present disclosure are specifically described with the accompanying drawings below. In the reference drawings, the same parts are denoted by the same numerals or symbols, and repeated description related to the same parts are in principle omitted. Furthermore, to keep the description of this specification simple, numerals or symbols of reference information, signals, physical quantities, elements or parts are given so as to omit the names of information, signals, physical quantities, elements or parts corresponding to the numerals or symbols. Moreover, in the embodiments of the present disclosure, a connection between multiple parts of a circuit formed by any circuit elements, lines and nodes is understood as an electrical connection unless otherwise specified.

FIG. 1 shows a structural diagram of a voltage generating circuit (temperature characteristic correction circuit) 1 according to an embodiment of the present disclosure. The voltage generating circuit 1 includes an operational amplifier 10, a voltage dividing circuit 20, a correction circuit 30 and an input voltage supply circuit 40. The operational amplifier 10, the voltage dividing circuit 20 and a correction circuit 30 form an amplifying circuit 2. In the first embodiment below, the amplifying circuit 2 does not include the correction circuit 30.

The operational amplifier 10 includes a non-inverting input terminal and an inverting input terminal as two input terminals, and includes an output terminal, from which an output voltage Vout is output. Moreover, the output terminal of the operational amplifier 10 is connected to an output node OUT, and the output voltage Vout of the voltage generating circuit 1 is supplied through the output node OUT to other back-stage circuits not shown in the drawing.

The voltage dividing circuit 20 is disposed between the output node OUT (further being an output terminal of the operational amplifier 10) and the ground. The ground has a 0 V potential used as a reference in the voltage generating circuit 1. The ground is an example of a predetermined potential terminal having a predetermined potential. The 0 V potential is sometimes also referred to as a ground potential. In the embodiments of the present disclosure, a voltage expressed without a specifically configured reference represents a potential observed from the ground. The voltage dividing circuit 20 includes a plurality of voltage dividing resistors, and the output voltage Vout is divided by the plurality of voltage dividing resistors to generate a feedback voltage Vfb corresponding to the output voltage Vout. The feedback voltage Vfb generated is supplied to the inverting input terminal of the operational amplifier 10.

The correction circuit 30 is disposed between a correction node (not shown in FIG. 1) disposed on the voltage dividing circuit 20 and the ground, is formed for a current to flow between the correction node and the ground. The current flowing between the correction node and the ground through the correction circuit 30 is also sometimes referred to as a correction current. The value of the current (correction current) is dependent on a temperature T. and the current (correction current) does not flow when the temperature T is in certain values. Specific examples of the correction circuit 30 are described below.

The temperature T is sometimes the temperature of the voltage generating circuit 1, sometimes the temperature of the amplifying circuit 2, and sometimes the temperature of a semiconductor device including the voltage generating circuit 1. The temperature T is sometimes the temperature of a constituent (a diode below) of the correction circuit 30. The semiconductor device including the voltage generating circuit 1 is an electronic component configured with elements comprising: a semiconductor chip, having a semiconductor integrated chip formed on a semiconductor substrate: a housing (a package), accommodating the semiconductor chip; and a plurality of external terminals, exposed to the outside the semiconductor device from the housing. The semiconductor device is formed by packaging the semiconductor chip in the housing (package) made of resin. The semiconductor integrated circuit includes therein the voltage generating circuit 1.

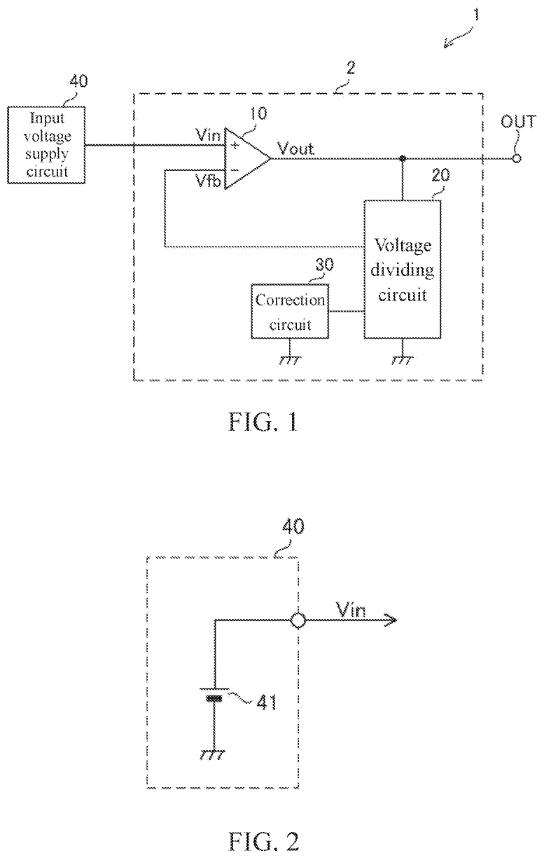

The input voltage supply circuit 40 generates an input voltage Vin to be input to the non-inverting input terminal of the operational amplifier 10, and supplies the input voltage Vin to the non-inverting input terminal of the operational amplifier 10. Moreover, as shown in FIG. 2, it is assumed that the input voltage supply circuit 40 is a reference voltage source 41 that generates a predetermined reference voltage, and it is assumed that the reference voltage output from the reference voltage source 41 is the input voltage Vin. The reference voltage has a predetermined DC voltage value.

The operational amplifier 10 controls the potential of the output terminal in a manner of having the voltage in the inverting input terminal and the voltage in the non-inverting input terminal be consistent with each other. That is to say, the operational amplifier 10 outputs the output voltage Vout from the output terminal in a manner of having the feedback voltage Vfb and the input voltage Vin be consistent with each other.

In this embodiment, unless otherwise specified, the input voltage Vin is a positive voltage. The operational amplifier 10 receives the supply of a supply voltage of the positive side and a supply voltage of the negative side, and is driven based on these supply voltages. The supply voltage of the positive side has a positive DC voltage (for example, 5V). The supply voltage of the negative side is 0 V. However, the supply voltage of the negative side can also be a negative DC current (for example, −5 V). The amplifying circuit 2 uses a voltage obtained by amplifying the input voltage Vin as the output voltage Vout. The denotation “AF” is used to represent an amplification factor of the amplifying circuit 2, and “AF=Vout/Vin” is used to represent the amplification factor AF.

In the multiple implementation examples below, specific configuration examples, operation examples, application techniques and variation techniques of the voltage generating circuit 1 are described. Unless otherwise specified and without any contradiction, the items described in this embodiment are applicable to the various embodiments below. In the various implementation examples, the description of the embodiments are adopted with preference in case of the presence of any items contradictory to the items described above. Provided there are not contradictions, the items described in any one of the embodiments below are also applicable to any other embodiment (that is to say, any two or more of the embodiments can be combined).

### First Embodiment

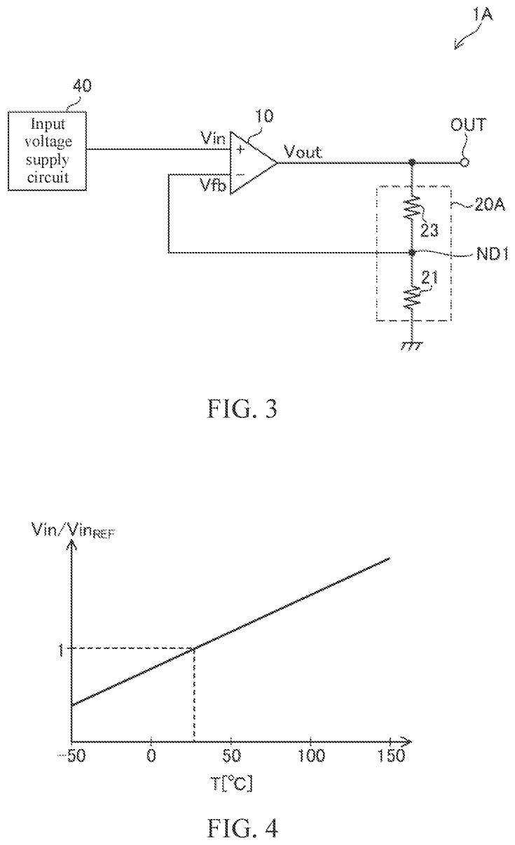

The first embodiment is described below. FIG. 3 shows a structural diagram of a voltage generating circuit 1A according to the first embodiment. The voltage generating circuit 1A is an example of the voltage generating circuit 1. The voltage dividing circuit 20 in the voltage generating circuit 1A is specifically referred as a voltage dividing circuit 20A. As shown in FIG. 3, the voltage generating circuit 1A includes the operational amplifier 10, the voltage dividing circuit 20A and the input voltage supply circuit 40, but excludes the correction circuit 30.

The voltage dividing circuit 20A includes a series circuit of voltage dividing resistors 21 and 23. In the voltage dividing circuit 20A, one terminal of the voltage dividing resistor 23 is connected to the output node OUT, and the other terminal of the voltage dividing resistor 23 is connected to a feedback node ND1. In the voltage dividing circuit 20A, one terminal of the voltage dividing resistor 21 is connected to the feedback node ND1, and the other terminal of the voltage dividing resistor 21 is connected to the ground. A voltage generated at the feedback node ND1 is the feedback voltage Vfb, and the feedback voltage Vfb is input to the inverting input terminal by connecting the feedback node ND1 to the inverting input terminal of the operational amplifier 10.

In the first embodiment, as shown in FIG. 4, it is assumed that the input voltage Vin equivalent to the output voltage of the reference voltage source 41 has positive temperature characteristics. The input voltage Vin having positive temperature characteristics implies that the input voltage Vin has a positive temperature coefficient, and so the input voltage Vin increases as the temperature T rises. Moreover, in the first embodiment, as shown in FIG. 4, the temperature T of the input voltage Vin is expressed by a linear function, and within a target temperature range, a change in the input voltage Vin under each unit change of the temperature T is constant. Moreover, the target temperature range is a temperature range between −50° C. and 150° C.; however, the target temperature range can be any as desired (the same applies to the embodiments below). The target temperature range is, for example, consistent with a category temperature range of the semiconductor device including the voltage generating circuit 1, or includes the entirety of or part of the category temperature range.

The denotation “Vin_{REF}” is used to represent the input voltage Vin when the temperature T is consistent with a specific reference temperature within the target temperature range. Thus, when the temperature T is consistent with the reference temperature, a ratio (Vin/Vin_{REF}) is “1”. The reference temperature is usually referred to as the room temperature, for example, 25° C.

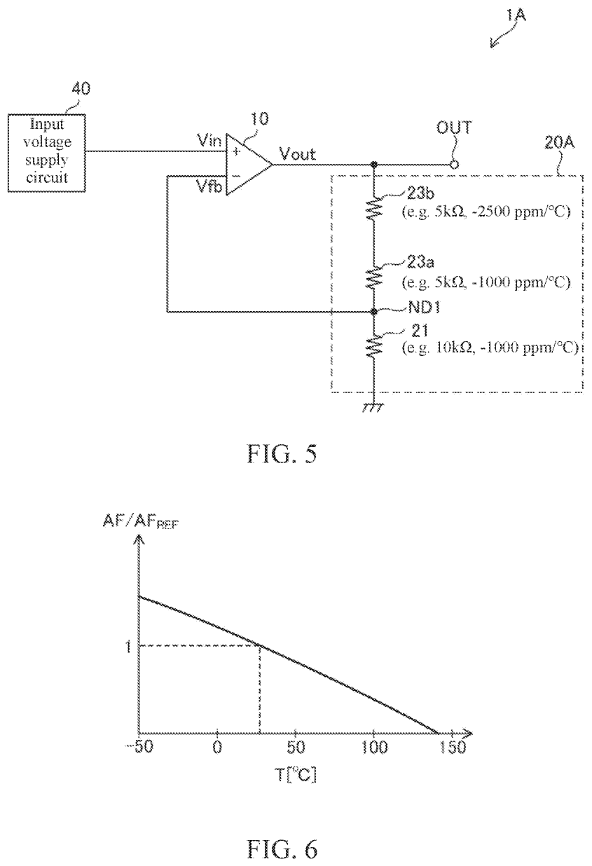

In the voltage generating circuit 1A, in order to counteract the change in the input voltage Vin dependent on the temperature T, the output voltage Vout is kept constant within a greater temperature range, and the structure in FIG. 5 is adopted. That is, specifically, the voltage dividing circuit 20A of the first embodiment includes a series circuit of voltage dividing resistors 23a and 23b, wherein the series circuit of the voltage dividing resistors 23a and 23b functions as the voltage dividing resistor 23 (referring to FIG. 3). More specifically, in the voltage generating circuit 1A in FIG. 5, one terminal of the voltage dividing resistor 23b is connected to the output node OUT, the other terminal of the voltage dividing resistor 23b is connected to a feedback node ND1 through the voltage dividing resistor 23a, and the feedback node ND1 is connected to the ground through the voltage dividing resistor 21.

Moreover, the voltage dividing resistors 21 and 23a are formed as first-type resistors, and the voltage dividing resistor 23b is formed as a second-type resistor. The first-type resistor and the second type-resistor have different temperature characteristics (temperature coefficient) from each other. Corresponding to the input voltage Vin having a positive coefficient, the first-type resistor and the second-type resistor are provided with negative temperature characteristics (a negative temperature coefficient). For example, the temperature coefficient of the first-type resistor is “−1000 ppm/° C.”, and the temperature coefficient of the second-type resistor is “−2500 ppm/° C.”. Moreover, for example, resistance values of the voltage dividing resistors 21, 23a and 23b at the reference temperature are respectively set to 10 kΩ, 5 kΩ and 5 kΩ. Thus, the amplification factor AF of the amplifying circuit including the operational amplifier 10 and the voltage dividing circuit 20A becomes “2” at the reference temperature, and decreases as the temperature T rises from the reference temperature.

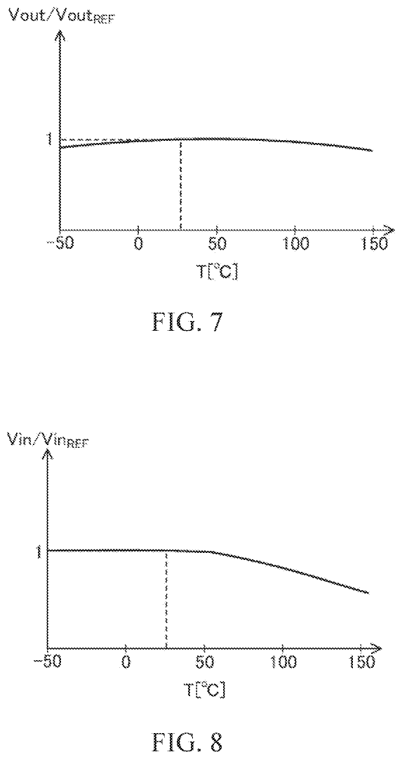

Refer to FIG. 6 and FIG. 7. The denotation “AF_{REF}” is used to represent the amplification factor AF when the temperature T and the reference temperature (25° C. herein) are consistent, and the denotation “Vout_{REF}” is used to represent the output voltage Vout when the temperature T and the reference temperature (25° C. herein) are consistent. Thus, when the temperature T is consistent with the reference temperature, the ratio (AF/AF_{REF}) and the ratio (Vou/Vout_{REF}) are both “1”. FIG. 6 shows temperature dependence of the ratio (AF/AF_{REF}) in the voltage generating circuit 1A in FIG. 5, and FIG. 7 shows temperature dependence of the ratio (Vout/Vout_{REF}) in the voltage generating circuit 1A in FIG. 5. The amplification factor AF has negative temperature characteristics by corresponding to the input voltage Vin having positive temperature characteristics, the influences imposed by the positive temperature characteristics of the input voltage Vin on the output voltage Vout can be counteracted, and as a result, the output voltage Vout can be kept substantially constant (near Vout_{REF}) within a greater temperature range.

### Second Embodiment

The second embodiment is described below. As shown in FIG. 4, when the input voltage Vin is expressed by a linear function of the temperature T, that is, the change in the input voltage Vin is linear with respect to the change in the temperature T, temperature characteristics can be satisfactorily corrected by the configuration of the first embodiment. The correction of temperature characteristics is implemented by generating the output voltage Vout that has less temperature dependence than that of the input voltage Vin. The amount of change in the output voltage Vout (for example, a difference between a maximum value and a minimum value of the output voltage Vout) generated within the target temperature range when the temperature T changes is configured to be less than the amount of change in the input voltage Vin (for example, a difference between a maximum value and a minimum value of the input voltage Vin) within the target temperature range when the temperature T changes. Therefore, the voltage generating circuit 1 can also be referred to as a temperature characteristic correction circuit.

The correction of the first embodiment is equivalent to a one-time correction. However, there are numerous situations where the input voltage Vin is not expressed by a linear function of the temperature T. and it is difficult to solve the issues by such one-time correction in these situations. In the second embodiment, it is assumed that the input voltage Vin has the temperature characteristics shown in FIG. 8. That is to say, in the second embodiment, “Vin/Vin_{REF}=1” is substantially maintained within the predetermined range of the low-temperature side. However, as the temperature T rises within the range of the high-temperature side, the input voltage Vin decreases, and such decreases have quadratic characteristics (that is to say, the input voltage Vin changes curvilinearly as the temperature T rises). In the example in FIG. 8, the range of the low-temperature side is a temperature range between −50° C. and around 50° C. and the range of the high-temperature side is a temperature range that exceeds the range of the low-temperature side. The target temperature range includes the range of the low-temperature side and the range of the high-temperature side.

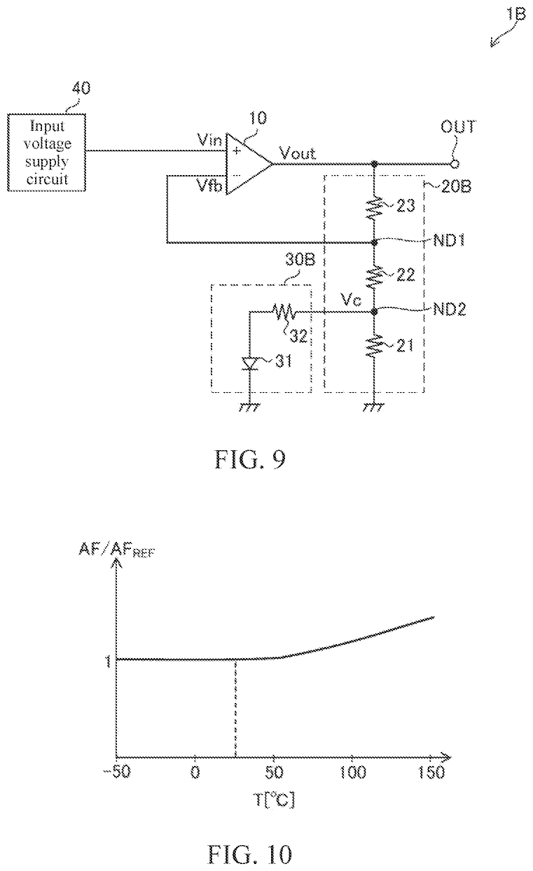

FIG. 9 shows a structural diagram of a voltage generating circuit 1B according to the second embodiment. The voltage generating circuit 1B is an example of the voltage generating circuit 1. The voltage dividing circuit 20 in the voltage generating circuit 1B is specifically referred as a voltage dividing circuit 20B. The voltage generating circuit 1B includes the operational amplifier 10, the voltage dividing circuit 20B and the input voltage supply circuit 40, and further includes a correction circuit 30B (referring to FIG. 1) as an example of the correction circuit 30.

The voltage dividing circuit 20B includes a series circuit of voltage dividing resistors 21 to 23. In the voltage dividing circuit 20B, a correction node ND2 is further provided in addition to the feedback node ND1. In the voltage dividing circuit 20B, one terminal of the voltage dividing resistor 23 is connected to the output node OUT, and the other terminal of the voltage dividing resistor 23 is connected to the feedback node ND1. In the voltage dividing circuit 20B, one terminal of the voltage dividing resistor 22 is connected to the feedback node ND1, and the other terminal of the voltage dividing resistor 22 is connected to the correction node ND2. In the voltage dividing circuit 20B, one terminal of the voltage dividing resistor 21 is connected to the correction node ND2, and the other terminal of the voltage dividing resistor 21 is connected to the ground.

The voltage dividing circuit 20B divides the output voltage Vout by the voltage dividing resistors 21 to 23, accordingly generates the feedback voltage Vfb at the feedback node ND1, and generates a voltage Vc different from the feedback voltage Vib at the correction node ND2. The voltages generated at the feedback node ND1 and the correction node ND2 correspond to the output voltage Vout. It is assumed herein that “Vout>0”, and so “Vout>Vfb>Vc>0”. As described above, the feedback voltage Vfb is input to the inverting input terminal by connecting the feedback node ND1 to the inverting input terminal of the operational amplifier 10.

The correction circuit 30B includes a diode 31 and an adjustment resistor 32. The diode 31 is a semiconductor diode formed by a semiconductor PN junction. The adjustment resistor 32 is connected in series to the diode 31, and a series circuit of the diode 31 and the adjustment circuit 32 is inserted between the correction node ND2 and the ground. In the voltage generating circuit 1B in FIG. 9, one terminal of the adjustment resistor 32 is connected to the correction node ND2, the other terminal of the adjustment resistor 32 is connected to an anode of the diode 31, and a cathode of the diode 31 is connected to the ground.

A resistance ratio between the voltage dividing resistors 21 and 22 is set based on the input voltage Vin(Vin_{REF}), so as to generate at the correction node ND2 a voltage equivalent to a forward voltage Vf of the diode 31 when a current starts flowing in the diode 31. The so-called current flowing in the diode 31 refers to a forward current (that is, a current that flows from the anode to the cathode). The same applies to any other diodes below.

A value of the current flowing in the diode 31 is below a predetermined value Ii when the temperature T is below a predetermined boundary temperature, exceeds the predetermined value Is when the temperature T exceeds the predetermined boundary temperature, and increases as the temperature T rises when the temperature T exceeds the predetermined boundary temperature. The predetermined value ii is an extremely minute value, and the current flowing in the diode 31 can be regarded as zero when the temperature T is below the predetermined boundary temperature. The boundary temperature is a temperature at a border between the range of the low-temperature side and the range of the high-temperature side, and is consistent with an upper limit of the range of the low-temperature side and a lower limit of the range of the high-temperature side.

Corresponding to the temperature T, a current flows in the diode 31. When the current flows in the diode 31, the voltage drop of the voltage dividing resistor 23 correspondingly increases because of the current, and so the amplification factor AF increases. That is to say, when the current flows in the diode 31, compared with a situation when the current does not flow in the diode 31, the amplification factor AF of the amplifying circuit 2 (an amplifying circuit including the operational amplifier 10, the voltage dividing circuit 20B and the correction circuit 30B in this embodiment) increases.

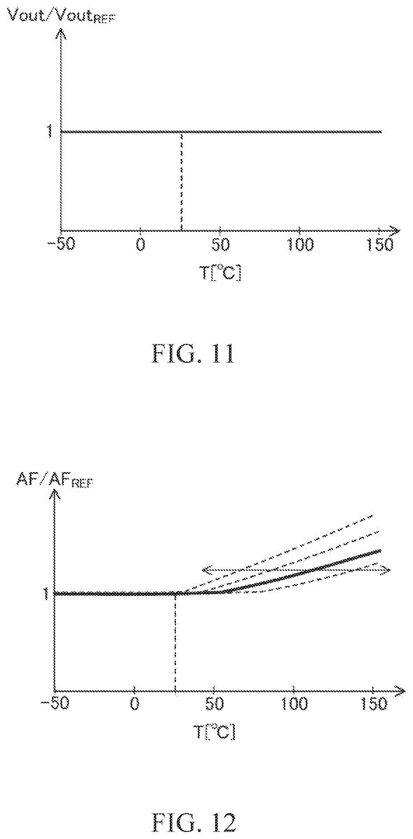

FIG. 10 shows temperature dependence of the ratio (AF/AF_{REF}) in the voltage generating circuit 1B in FIG. 9, and FIG. 11 shows temperature dependence of the ratio (Vout/Vout_{REF}) in the voltage generating circuit 1B in FIG. 9. Within the range of the low-temperature side, as shown in FIG. 8, “Vin/Vin_{REF}=1”, and on the other hand, “AF/AF_{REF}=1” since no current flows in the diode 31. Within the range of the high-temperature side, as shown in FIG. 8, the ratio (Vin/Vin_{REF}) decreases as the temperature T rises. Within the range of the high-temperature side, the voltage drop of the voltage dividing resistor 23 correspondingly increases because of the current flowing in the diode 31, and so the ratio (AF/AF_{REF}) becomes greater than 1, and based on the characteristics of the diode 31, the ratio (AF/AF_{REF}) increases as the temperature T rises. As a result, the decrease in the ratio (Vin/VIN_{REF}) within the range of the high-temperature side counteracts the increases in the ratio (AF/AF_{REF}), and as shown in FIG. 11, the output voltage Vout can be kept substantially constant (near Vout_{REF}) at the entire ranges of the low-temperature side and the high-temperature side.

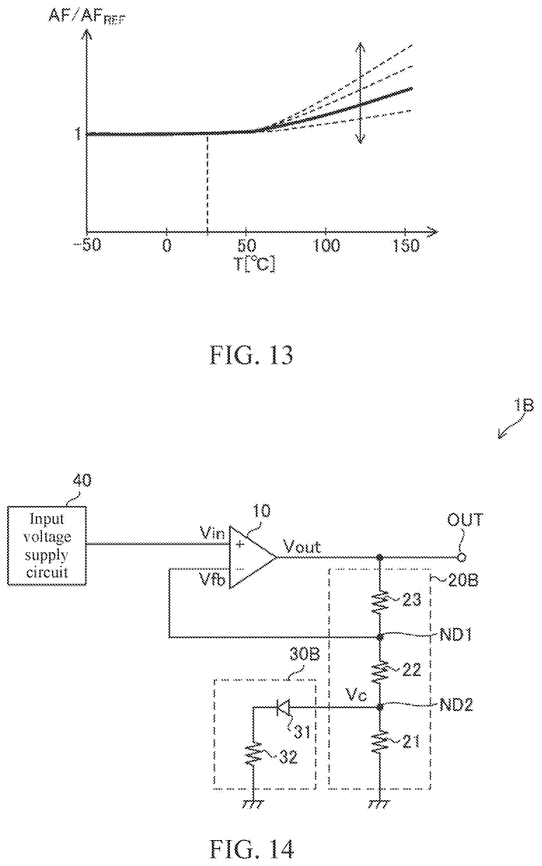

Moreover, in the voltage generating circuit 1B, by adjusting the resistance ratio between the voltage dividing resistors 21 and 22, the temperature T that causes the value of the ratio (AF/AF_{REF}) to start increasing from “1” can be adjusted. FIG. 12 shows a diagram of the concept of such adjustment. Moreover, with the adjustment resistor 32 inserted, a rising slope of the ratio (AF/AF_{REF}) can be adjusted as desired. FIG. 13 shows a diagram of the concept of adjustment related to the slope. That is to say, by adjusting the value of the resistor 32, the rising slope of the ratio (AF/AF_{REF}) that increases when the ratio (AF/AF_{REF}) increases corresponding to the rise in the temperature T can be adjusted.

Moreover, in the correction circuit 30B, the positions of the inserted diode 31 and the adjustment resistor 32 can be swapped. That is to say, as shown in FIG. 14, in the correction circuit 30B, on the basis that the anode of the diode 31 is connected to the correction node ND2, the cathode of the diode 31 is connected to one terminal of the adjustment resistor 32, and the other terminal of the adjustment resistor 32 is connected to the ground.

### Third Embodiment

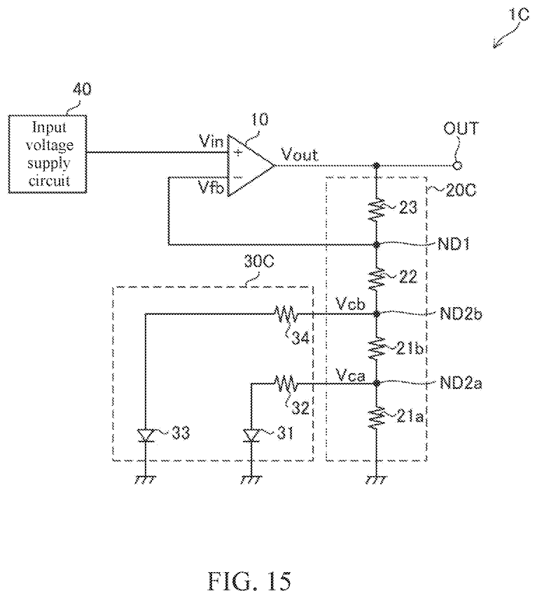

The third embodiment is described below. The number of diodes disposed in the correction circuit 30 can also be plural. FIG. 15 shows a configuration example with two diodes provided. FIG. 15 shows a structural diagram of a voltage generating circuit 1C according to the third embodiment. The voltage generating circuit 1C is an example of the voltage generating circuit 1. The voltage dividing circuit 20 and the correction circuit 30 in the voltage generating circuit 1C are specifically referred as a voltage dividing circuit 20C and a correction circuit 30C. The voltage generating circuit 1C includes the operational amplifier 10, the voltage dividing circuit 20C, the correction circuit 30C and the input voltage supply circuit 40.

The voltage dividing circuit 20C includes a series circuit of voltage dividing resistors 21a, 21b. 22 and 23. In the voltage dividing circuit 20C, correction nodes ND2a and ND2b are further provided in addition to the feedback node ND1. That is to say, in the voltage dividing circuit 20B in FIG. 9, the voltage dividing resistor 21 is divided into the voltage dividing resistors 21a and 21b, and a connection node between the voltage dividing resistors 21a and 21b is further added as one correction node, accordingly forming the voltage dividing circuit 20C.

In the voltage dividing circuit 20C, one terminal of the voltage dividing resistor 23 is connected to the output node OUT, and the other terminal of the voltage dividing resistor 23 is connected to the feedback node ND1. In the voltage dividing circuit 20C, one terminal of the voltage dividing resistor 22 is connected to the feedback node ND1, and the other terminal of the voltage dividing resistor 22 is connected to the correction node ND2b. In the voltage dividing circuit 20C, one terminal of the voltage dividing resistor 21b is connected to the correction node ND2b, and the other terminal of the voltage dividing resistor 21b is connected to the correction node ND2a. In the voltage dividing circuit 20C, one terminal of the voltage dividing resistor 21a is connected to the correction node ND2a, and the other terminal of the voltage dividing resistor 21a is connected to the ground.

The voltage dividing circuit 20C divides the output voltage Vout by the voltage dividing resistors 21a, 21b, 22 and 23, and accordingly generates the feedback voltage Vfb at the feedback node ND1, generates a voltage Vca different from the feedback voltage Vfb at the correction node ND2a, and generates a voltage Vcb different from the feedback voltage Vfb at the correction node ND2b. The voltages generated at the feedback node ND1 and the correction nodes ND2a and ND2b correspond to the output voltage Vout. It is assumed herein that “Vout>0”, and so “Vout>Vfb>Vcb>Vca>0”. As described above, the feedback voltage Vfb is input to the inverting input terminal by connecting the feedback node ND1 to the inverting input terminal of the operational amplifier 10.

The correction circuit 30C includes the diode 31, the adjustment resistor 32, a diode 33 and an adjustment resistor 34. The diodes 31 and 33 are semiconductor diodes formed by a semiconductor PN junction. The adjustment resistor 32 is connected in series to the diode 31, and a series circuit of the diode 31 and the adjustment resistor 32 is inserted between the correction node ND2a and the ground. In the voltage generating circuit 1C in FIG. 15, one terminal of the adjustment resistor 32 is connected to the correction node ND2a, the other terminal of the adjustment resistor 32 is connected to the anode of the diode 31, and the cathode of the diode 31 is connected to the ground. The adjustment resistor 34 is connected in series to the diode 33, and a series circuit of the diode 33 and the adjustment resistor 34 is inserted between the correction node ND2b and the ground. In the voltage generating circuit 1C in FIG. 15, one terminal of the adjustment resistor 34 is connected to the correction node ND2b, the other terminal of the adjustment resistor 34 is connected to the anode of the diode 33, and the cathode of the diode 33 is connected to the ground.

Corresponding to the temperature T, a current flows in the diodes 31 and 33. When the current flows in the diode 31, the voltage drop of the voltage dividing resistor 23 correspondingly increases because of the current, and so the amplification factor AF increases. That is to say, when the current flows in the diode 31, compared with a situation when the current does not flow in the diode 31, the amplification factor AF of the amplifying circuit 2 (an amplifying circuit including the operational amplifier 10, the voltage dividing circuit 20C and the correction circuit 30C in this embodiment) increases. Similarly, when the current flows in the diode 33, the voltage drop of the voltage dividing resistor 23 correspondingly increases because of the current, and so the amplification factor AF increases. That is to say, when the current flows in the diode 33, compared with a situation when the current does not flow in the diode 33, the amplification factor AF of the amplifying circuit 2 (an amplifying circuit including the operational amplifier 10, the voltage dividing circuit 20C and the correction circuit 30C in this embodiment) increases.

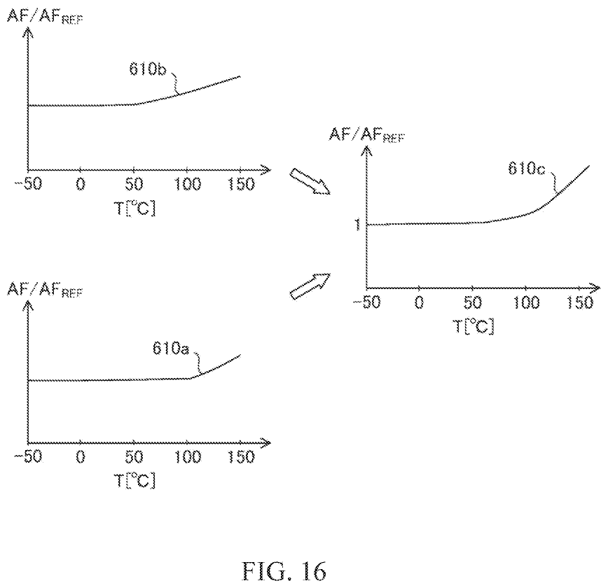

FIG. 16 shows waveforms 610a, 610b and 610c associated with the voltage generating circuit 1C in FIG. 15. The waveforms 610a, 610b and 610c respectively represent temperature dependence of the ratio (AF/AF_{REF}) in the voltage generating circuit 1C. The waveform 610a represents the temperature dependence of the ratio (AF/AF_{REF}) under the assumption that the series circuit of the diode 33 and the adjustment resistor 34 is removed from the correction circuit 30C. The waveform 610b represents the temperature dependence of the ratio (AF/AF_{REF}) under the assumption that the series circuit of the diode 31 and the adjustment resistor 32 is removed from the correction circuit 30C. The waveform 610c represents the temperature dependence of the ratio (AF/AF_{REF}) when the series circuit of the diode 31 and the adjustment resistor 32 and the series circuit of the diode 33 and the adjustment resistor 34 are provided in the correction circuit 30C as shown in FIG. 15.

A value of the current flowing in the diode 33 is below the predetermined value L when the temperature T is below a predetermined first boundary temperature, exceeds the predetermined value Ii when the temperature T exceeds the predetermined first boundary temperature, and increases as the temperature T rises when the temperature T exceeds the predetermined first boundary temperature. A value of the current flowing in the diode 31 is below the predetermined value Ii when the temperature T is below a predetermined second boundary temperature, exceeds the predetermined value I_{J} when the temperature T exceeds the predetermined second boundary temperature, and increases as the temperature T rises when the temperature T exceeds the predetermined second boundary temperature. The predetermined value I_{J} is an extremely minute value, the current flowing in the diode 33 can be regarded as zero when the temperature T is below the predetermined first boundary temperature, and the current flowing in the diode 31 can be regarded as zero when the temperature T is below the predetermined second boundary temperature.

It is assumed herein that the diodes 31 and 33 have the same characteristics. Thus, compared to the correction node ND2a, the correction node ND2b is applied with a higher voltage, and so the temperature T at which the current starts flowing in the diode 33 is lower than the temperature T at which the current starts flowing in the diode 31. That is to say, the first boundary temperature (for example, 50° C.) is lower than the second boundary temperature (for example, 100° C.). The situation can be discovered according to the waveform 610b depending on the current flowing in the diode 33, and the waveform 610a depending on the current flowing in the diode 31 (referring to FIG. 16). Moreover, the waveform 610c has characteristics obtained by coinciding the characteristics of the waveform 610a with the characteristics of the waveform 610b.

When the ratio (Vin/Vin_{REF}) has characteristics (temperature characteristics) opposite to the characteristics shown by the waveform 610c, the output voltage Vout in the voltage generating circuit 1C is kept constant in a larger temperature range (for example, being kept near Vout_{REF} within the entire target temperature range), which is however not specifically shown in the drawing.

Thus, with the multiple diodes provided in the correction circuit 30, various temperature characteristics of the input terminal Vin can be responded to, so as to keep the output voltage Vout within a greater temperature range.

Although a configuration of two diodes provided in the correction circuit 30 is used as the correction circuit 30C, three or more diodes can be provided as desired in the correction circuit 30. At this point in time, the diodes in the correction circuit 30 can be connected in series to the respective corresponding adjustment resistors. That is to say, if three diodes are to be provided in the correction circuit 30, a variation can be implemented by using the structure shown in FIG. 15 as a reference; that is, the voltage dividing resistor 22 is divided into two resistors, namely first and second voltage dividing resistors, a third correction node different from the correction nodes ND2a and ND2b is set between the first and second voltage dividing resistors, and a series circuit of a third diode and a third adjustment resistor is inserted between the third correction node and the ground. At this point in time, it can be regarded that the diode 31 and the adjustment resistor 32 are used to function as a first diode and a first adjustment resistor, the diode 33 and the adjustment resistor 34 are used to function as a second diode and a second adjustment resistor, and the correction nodes ND2a and ND2b are used to function as first and second correction nodes. Four or more diodes can also be provided in the correction circuit 30 based on the same concept.

Moreover, the structure in FIG. 9 can also be similar to a variation structure in FIG. 14, and have, in any one among the more than one group formed by the diodes and the adjustment resistors provided in the correction circuit 30, the diode disposed on the side of the correction node and the adjustment resistor disposed on the side of the ground. That is to say, for a structure as that in FIG. 15, the structure in FIG. 15 can be used as a reference to implement a variation that connects the anode of the diode 31 to the connection node ND2a and connects the cathode of the diode 31 to the ground through the adjustment resistor 32. In addition to the above, or alternatively, in another variation implementation, the anode of the diode 33 is connected to the correction node ND2b and the cathode of the diode 33 is connected to the ground through the adjustment resistor 34.

### Fourth Embodiment

The fourth embodiment is described below. In the second and third embodiments, it is assumed that all voltage dividing resistors included in the voltage dividing circuit 20 have the same temperature characteristics (the same temperature coefficient) as each other. That is to say, the following assumption is made for the second and third embodiments, for the structure in FIG. 9, the temperature coefficients of the voltage dividing resistors 21 to 23 are all, for example, set to “−1000 ppm/° C.”; for the structure in FIG. 15, the temperature coefficients of the voltage dividing resistors 21a, 21b, 22 and 23 are all set to “−1000 ppm/° C.” (with however errors existing between actual temperature coefficients).

However, according to the temperature characteristics of the input voltage Vin, the correction method of the first embodiment and the correction method of the second or third embodiment can be combined. Accordingly, one-time correction and correction on the high-temperature side (offset correction) can be simultaneously implemented.

Specifically, for the structure in FIG. 9, the structure in FIG. 9 can be used as a reference to divide the voltage dividing resistor 23 into the voltage dividing resistors 23a and 23b (referring to FIG. 5), and the voltage dividing resistors 21, 22 and 23a are formed as first-type resistors and the voltage dividing resistor 23b is formed as a second-type resistor. The same applies to the structure shown in FIG. 15. Definitions of the first-type resistor and the second-type resistor are as described in the first embodiment. Temperature coefficients of various resistors are appropriately set, given that they are set according to the temperature characteristics of the input voltage Vin. Moreover, for the structure in FIG. 9, instead of dividing the voltage dividing resistor 23 into the voltage dividing resistors 23a and 23b, only the voltage dividing resistors 21 and 22 are formed as first-type resistors, and the voltage dividing resistor 23 is formed as a second-type resistor (the same applies to the structure in FIG. 15).

### Fifth Embodiment

The fifth embodiment is described below. In the voltage generating circuit 1, the output voltage Vout can also be a negative voltage. That is to say, for example, if the input voltage Vin is a negative voltage, when a negative DC voltage (−5 V) used as a supply voltage on the negative side is supplied to the operational amplifier 10, the output voltage Vout in a negative voltage is obtained.

When the output voltage Vout is a negative voltage, the forward direction of the diodes provided in the correction circuit 30 is opposite to those of the second and third embodiment. That is to say, for example, when the output voltage Vout is a negative voltage in the voltage generating circuit 1B in FIG. 9, by merely modifying the correction circuit 30B, a direction from the ground to the correction node ND2 can be provided as a forward direction of the diode 31. Similarly, for example, when the output voltage Vout is a negative voltage in the voltage generating circuit 1C in FIG. 15, by merely modifying the correction circuit 30C, a direction from the ground to the correction node ND2a becomes a forward direction for the diode 31, and a direction from the ground to the correction node ND2b becomes a forward direction for the diode 33.

### Sixth Embodiment

The sixth embodiment is described below. The voltage generating circuit 1 of the various embodiments above can be assembled to any circuit that requires the output voltage Vout. For example, an analog-to-digital converter (ADC, not shown) including the voltage generating circuit 1 can be formed, so as to use the output voltage Vout that is kept constant as a reference for converting analog signals into digital signals. In addition, for example, the output voltage Vout can also be used as a reference voltage of a DC/DC converter.

### Seventh Embodiment

The seventh embodiment is described below. In this seventh embodiment, variation techniques, application techniques and supplementary items suitable for the various embodiments are described.

The description above provides examples in which the input voltage Vin is a reference voltage generated by the reference voltage source 41 (referring to FIG. 2). However, the input voltage supply circuit 40 can be any as desired, and is not limited to the reference voltage source 41, given that a circuit capable of generating and outputting the input voltage Vin is used.

In the correction circuit 30, the adjustment resistor (for example, the correction resistor 32) to be connected in series to the diode (for example, the diode 31) can also be removed. In this case, only the diode is inserted between the correction node and the ground. In a situation where the adjustment resistor is removed, the slope cannot be adjusted by using the adjustment resistor as shown in FIG. 13, and so the slope becomes steep, causing an issue that the desired correction cannot be achieved. Therefore, an adjustment resistor is preferably provided.

A transistor such as a bipolar transistor or a metal-oxide-semiconductor field-effect transistor (MOSFET) can also be connected to a diode so as to form the diode 31. For example, an N-channel MOSFET with short circuitry between the drain and the gate can also be used as the diode 31. The same applies to the other diodes (for example, the diode 33 in FIG. 15) included in the correction circuit 30.

The diode 31 can also be replaced by a circuit having equivalent functions and equivalent temperature characteristics as the diode 31.

In the present disclosure, the expression of a first physical quantity being “the same as” a second physical quantity should be understood as a concept including an error. That is to say, the expression of a first physical quantity being “the same as” a second physical quantity means that the first physical quantity is designed or manufactured in the aim of being “the same as” the second physical quantity: even if an error exists between the first and second physical quantities, it is to be understood that the first physical quantity and the second physical quantity are “the same”. Other expression similar to “the same (as)” (for example, “equivalent to” or “consistent with”) shall be understood in this way.

Various modifications may be made to the embodiments of the present disclosure within the scope of the technical concept disclosed in the claims. The embodiments above are only examples of possible implementations of the present disclosure, and the meanings of the terms of the present disclosure or the constituent components are not limited to the meanings of the terms used in the embodiments above. The specific numerical values used in the description are simple examples, and these numerical values may be modified to various other numerical values.

### Notes

Specific configuration examples of the embodiments of the present disclosure are described in the notes below.

An amplifying circuit (amplifying circuit 2; referring to FIG. 1, FIG. 9 and FIG. 15) according to an aspect of the present disclosure is configured as (a first configuration) including the following components: an operational amplifier (10), including a first input terminal, a second input terminal and an output terminal, and configured to be capable of outputting an output voltage (Vout) corresponding to an input voltage (Vin) from the output terminal to the first input terminal; a voltage dividing circuit (20, 20B. 20C), including a series circuit of a plurality of voltage dividing resistors disposed between the output terminal and a predetermined potential terminal, wherein the series circuit includes a feedback node (ND1) connected to the second input terminal and a correction node different from the feedback node: and a correction circuit (30, 30B, 30C), including a diode inserted between the correction node and the predetermined potential terminal.

Accordingly, in a situation w % here a temperature rises and an input voltage changes non-linearly, an output voltage with less temperature dependence than that of the input voltage can be generated. That is to say, an amplifying circuit that helps reduce temperature dependence of a voltage can be formed.

The amplifying circuit can also be configured as (a second configuration) below: in the amplifying circuit of the first configuration (referring to FIG. 9), the correction circuit includes the diode (31) and an adjustment resistor (32) connected in series to the diode, and a series circuit of the diode and the adjustment resistor is inserted between the correction node and the predetermined potential terminal.

With the adjustment resistor provided, it is easy to adjust temperature characteristics of the output voltage.

The amplifying circuit can also be configured as (a third configuration) below: in the amplifying circuit of the first or second configuration (referring to FIG. 9), a current flows between the correction node and a reference potential terminal through the diode, wherein the current corresponds to a temperature of the amplifying circuit, and an amplification factor of the amplifying circuit changes when the current flows, as compared with a situation when the current does not flow.

With the change in the amplification factor caused by the current flowing in the diode, the temperature dependence of the input voltage can be counteracted, resulting in an output voltage with less temperature dependence.

The amplifying circuit can also be configured as (a fourth configuration) below: in the amplifying circuit of any of the first to third configurations (referring to FIG. 9), the output voltage is divided by the plurality of voltage dividing resistors (21 to 23), a feedback voltage (Vfb) corresponding to the output voltage is generated in the feedback node (ND1), and another voltage (Vc) corresponding to the output voltage is generated in the correction node (ND2).

The amplifying circuit can also be configured as (a fifth configuration) below: in the amplifying circuit of the first configuration (referring to FIG. 15), the voltage dividing circuit includes a plurality of different correction nodes (ND2a and ND2b) in the series circuit, the correction circuit includes a plurality of diodes (31 and 33) corresponding to the plurality of correction nodes, and for each correction node, a corresponding diode is inserted between the correction node and the predetermined potential terminal.

With the plurality of diodes provided, various temperature characteristics of the input voltage can be responded to.

The amplifying circuit can also be configured as (a sixth configuration) below: in the amplifying circuit of the fifth configuration (referring to FIG. 15), the correction circuit includes a plurality of correction nodes and a plurality of adjustment resistors (32 and 34) corresponding to the plurality of diodes, and for each correction node, a series circuit of the corresponding diode and the corresponding adjustment resistor is inserted between the correction node and the predetermined potential terminal.

With the adjustment resistor provided, it is easy to adjust temperature characteristics of the output voltage.

The amplifying circuit can also be configured as (a seventh configuration) below: in the amplifying circuit of the fifth or sixth configuration (referring to FIG. 15), corresponding to the temperature of the amplifying circuit and among the plurality of diodes, a current flows through one or more diodes between one or more correction nodes corresponding to the one or more diodes and the reference potential terminal, and an amplification factor of the amplifying circuit changes when the current flows, as compared with a situation when the current does not flow.

With the change in the amplification factor caused by the current flowing in the diode, the temperature dependence of the input voltage can be counteracted, resulting in an output voltage with less temperature dependence.

The amplifying circuit can also be configured as (an eighth configuration) below: in the amplifying circuit of any of the fifth to seventh configurations (referring to FIG. 15), the output voltage is divided by the plurality of voltage dividing resistors (21a, 21b, 22 and 23), a feedback voltage (Vfb) corresponding to the output voltage is generated in the feedback node (ND1), and a plurality of other voltages (Vca and Vcb) corresponding to the output voltage are generated in the plurality of correction nodes (ND2a and ND2b).

A voltage generating circuit (referring to FIG. 1) according to an aspect of the present disclosure is configured as (a ninth configuration) comprising: the amplifying circuit (2) of any one of the first to eighth configurations; and an input voltage supply circuit (40), configured to be capable of supplying an input voltage (Vin) to the first input terminal.

1. An amplifying circuit, comprising:
an operational amplifier, including a first input terminal, a second input terminal and an output terminal, and configured to be capable of outputting an output voltage corresponding to an input voltage to the first input terminal from the output terminal;
a voltage dividing circuit, including a series circuit of a plurality of voltage dividing resistors disposed between the output terminal and a predetermined potential terminal, wherein the series circuit includes a feedback node connected to the second input terminal and a correction node different from the feedback node; and
a correction circuit, including a diode inserted between the correction node and the predetermined potential terminal.

2. The amplifying circuit of claim 1, wherein
the correction circuit includes the diode and an adjustment resistor connected in series to the diode, and
an series circuit of the diode and the adjustment resistor is inserted between the correction node and the predetermined potential terminal.

3. The amplifying circuit of claim 1, wherein
a current flows between the correction node and a reference potential terminal through the diode, wherein the current corresponds to a temperature of the amplifying circuit, and
an amplification factor of the amplifying circuit changes when the current flows, as compared with a situation when the current does not flow.

4. The amplifying circuit of claim 2, wherein
a current flows between the correction node and a reference potential terminal through the diode, wherein the current corresponds to a temperature of the amplifying circuit, and
an amplification factor of the amplifying circuit changes when the current flows, as compared with a situation when the current does not flow.

5. The amplifying circuit of claim 1, wherein
the output voltage is divided by the plurality of voltage dividing resistors,
a feedback voltage corresponding to the output voltage is generated in the feedback node, and
another voltage corresponding to the output voltage is generated in the correction node.

6. The amplifying circuit of claim 2, wherein
the output voltage is divided by the plurality of voltage dividing resistors,
a feedback voltage corresponding to the output voltage is generated in the feedback node, and
another voltage corresponding to the output voltage is generated in the correction node.

7. The amplifying circuit of claim 3, wherein
the output voltage is divided by the plurality of voltage dividing resistors,
a feedback voltage corresponding to the output voltage is generated in the feedback node, and
another voltage corresponding to the output voltage is generated in the correction node.

8. The amplifying circuit of claim 4, wherein
the output voltage is divided by the plurality of voltage dividing resistors,
a feedback voltage corresponding to the output voltage is generated in the feedback node, and
another voltage corresponding to the output voltage is generated in the correction node.

9. The amplifying circuit of claim 1, wherein
the voltage dividing circuit includes a plurality of different correction nodes in the series circuit,
the correction circuit includes a plurality of diodes corresponding to the plurality of correction nodes, and
for each correction node, a corresponding diode is inserted between the correction node and the predetermined potential terminal.

10. The amplifying circuit of claim 9, wherein
the correction circuit includes a plurality of correction nodes and a plurality of adjustment resistors corresponding to the plurality of diodes,
for each correction node, a series circuit of the corresponding diode and the corresponding adjustment resistor is inserted between the correction node and the predetermined potential terminal.

11. The amplifying circuit of claim 9, wherein
corresponding to the temperature of the amplifying circuit and among the plurality of diodes, a current flows through one or more diodes between one or more correction nodes corresponding to the one or more diodes and a reference potential terminal, and
an amplification factor of the amplifying circuit changes when the current flows, as compared with a situation when the current does not flow.

12. The amplifying circuit of claim 10, wherein
corresponding to the temperature of the amplifying circuit and among the plurality of diodes, a current flows through one or more diodes between one or more correction nodes corresponding to the one or more diodes and a reference potential terminal, and
an amplification factor of the amplifying circuit changes when the current flows, as compared with a situation when the current does not flow.

13. The amplifying circuit of claim 9, wherein
the output voltage is divided by the plurality of voltage dividing resistors,
a feedback voltage corresponding to the output voltage is generated in the feedback node, and
a plurality of other voltages corresponding to the output voltage are generated in the plurality of correction nodes.

14. The amplifying circuit of claim 10, wherein
the output voltage is divided by the plurality of voltage dividing resistors,
a feedback voltage corresponding to the output voltage is generated in the feedback node, and
a plurality of other voltages corresponding to the output voltage are generated in the plurality of correction nodes.

15. The amplifying circuit of claim 11, wherein
the output voltage is divided by the plurality of voltage dividing resistors,
a feedback voltage corresponding to the output voltage is generated in the feedback node, and
a plurality of other voltages corresponding to the output voltage are generated in the plurality of correction nodes.

16. The amplifying circuit of claim 12, wherein
the output voltage is divided by the plurality of voltage dividing resistors,
a feedback voltage corresponding to the output voltage is generated in the feedback node, and
a plurality of other voltages corresponding to the output voltage are generated in the plurality of correction nodes.

17. A voltage generating circuit, comprising:
the amplifying circuit of claim 1; and
an input voltage supply circuit, configured to be capable of supplying an input voltage to the first input terminal.

18. A voltage generating circuit, comprising:
the amplify ing circuit of claim 2; and
an input voltage supply circuit, configured to be capable of supplying an input voltage to the first input terminal.

19. A voltage generating circuit, comprising:
the amplify ing circuit of claim 3; and
an input voltage supply circuit, configured to be capable of supplying an input voltage to the first input terminal.

20. A voltage generating circuit, comprising:
the amplifying circuit of claim 9; and
an input voltage supply circuit, configured to be capable of supplying an input voltage to the first input terminal.
